(19) United States
(12) Patent Application Publication
(10) Pub. No.: US 2019/0306388 A1
(43) Pub. Date: Oct. 3, 2019

(54) IMAGE SENSOR AND CAMERA

(71) Applicant: NIKON CORPORATION, Tokyo (JP)

(72) Inventor: Shigeru MATSUMOTO, Sagamihara-shi (JP)

(73) Assignee: NIKON CORPORATION, Tokyo (JP)

(21) Appl. No.: 16/332,438

(22) PCT Filed: Sep. 29, 2017
(86) PCT No.: PCT/JP2017/035756

§ 371 Date: Jun. 13, 2019

(30) Foreign Application Priority Data
Sep. 29, 2016 (JP) 2016-192251

(51) Int. Cl. H04N 5/225; H04N 5/341; H01L 27/142; H01L 27/146

(52) U.S. Cl. CPC H04N 5/2254; H01L 27/14603; H01L 27/142; H04N 5/341

(57) ABSTRACT

An image sensor, includes: a first pixel, having a photoelectric conversion unit that generates an electric charge through photoelectric conversion of light having entered therein, which outputs a signal generated based upon the electric charge generated in the photoelectric conversion unit; second pixels, each having a filter unit that can be switched to a light-shielding state in which light is blocked or to a transmissive state in which light is transmitted, and a photoelectric conversion unit that generates an electric charge through photoelectric conversion of light transmitted through the filter unit, which output signals each generated based upon the electric charge generated in the photoelectric conversion unit; an exposure control unit that switches between first exposure control under which the filter unit of the second pixel is set in a transmissive state and light having entered the first pixel and the second pixel undergoes photoelectric conversion, and second exposure control under which the filter unit of the second pixel is set in a light-shielding state and light having entered the first pixel undergoes photoelectric conversion while an electric charge accumulated in the photoelectric conversion unit of the second pixel is held in the photoelectric conversion unit; and an output control unit that first executes the first exposure control to output signals from the first pixel and specific second pixels among the second pixels and then executes the second exposure control so as to output signals from the first pixel and second pixels other than the specific second pixel among the second pixels.

### TECHNICAL FIELD

The present invention relates to an image sensor and a camera.

### BACKGROUND ART

There is an image capturing device known in the related art that generates still image data while capturing a video image (PTL 1). However, there is an issue to be addressed in the image capturing device in the related art in that the frame rate becomes lower during a video shoot.

### CITATION LIST

### Patent Literature

PTL 1: Japanese Laid Open Patent Publication No. 2007-150439

### SUMMARY OF INVENTION

According to the first aspect of the present invention, an image sensor, comprises: a first pixel, having a photoelectric conversion unit that generates an electric charge through photoelectric conversion of light having entered therein, which outputs a signal generated based upon the electric charge generated in the photoelectric conversion unit; second pixels, each having a filter unit that can be switched to a light-shielding state in which light is blocked or to a transmissive state in which light is transmitted, and a photoelectric conversion unit that generates an electric charge through photoelectric conversion of light transmitted through the filter unit, which output signals each generated based upon the electric charge generated in the photoelectric conversion unit; an exposure control unit that switches between first exposure control under which the filter unit of the second pixel is set in a transmissive state and light having entered the first pixel and the second pixel undergoes photoelectric conversion, and second exposure control under which the filter unit of the second pixel is set in a light-shielding state and light having entered the first pixel undergoes photoelectric conversion while an electric charge accumulated in the photoelectric conversion unit of the second pixel is held in the photoelectric conversion unit; and an output control unit that first executes the first exposure control to output signals from the first pixel and specific second pixels among the second pixels and then executes the second exposure control so as to output signals from the first pixel and second pixels other than the specific second pixel among the second pixels.

According to the second aspect, a camera comprises: a first pixel, having a photoelectric conversion unit that generates an electric charge through photoelectric conversion of incident light, which outputs a signal generated based upon the electric charge generated in the photoelectric conversion unit; second pixels, each having a filter unit that is switched to a light-shielding state, in which incident light is blocked, or to a transmissive state, in which incident light is transmitted, and a photoelectric conversion unit that generates an electric charge through photoelectric conversion of light transmitted through the filter unit and accumulates the electric charge, which output signals each generated based upon the electric charge generated in the photoelectric conversion unit; an exposure control unit that switches between first exposure control under which the filter unit of the second pixel is set in a transmissive state and light having entered the first pixel and the second pixel undergoes photoelectric conversion, and second exposure control under which the filter unit of the second pixel is set in a light-shielding state and light having entered the first pixel undergoes photoelectric conversion while an electric charge accumulated in the photoelectric conversion unit of the second pixel is held in the photoelectric conversion unit; and an output control unit that first executes the first exposure control to output signals from the first pixel and specific second pixels among the second pixels and then executes the second exposure control so as to output signals from the first pixel and second pixels other than the specific second pixel among the second pixels.

According to the third aspect, an image sensor comprises: a plurality of pixels each having a photoelectric conversion unit; a first readout unit that reads out signals at specific pixels among the plurality of pixels as video image signals; a storage unit in which signals from a plurality of pixels are stored in relation to a single readout operation among a plurality of video image signal readout operations executed by the first readout unit; and a second readout unit that reads out the signals stored in the storage unit as still image signals.

According to the fourth aspect, an image sensor comprises: a plurality of pixels, each having a filter unit that can be switched to a light-shielding state in which light is blocked or to a transmissive state in which light is transmitted, a photoelectric conversion unit that generates an electric charge through photoelectric conversion of light having been transmitted through the filter unit, and an output unit that outputs a signal generated based upon the electric charge generated in the photoelectric conversion unit; and a control unit that first outputs signals through output units of specific pixels among the plurality of pixels and then sets filter units of the pixels other than the specific pixels in a light-shielding state so as to allow signals to be output through the output units thereof.

According to the fifth aspect, an image sensor, comprises: a first pixel, having a photoelectric conversion unit that generates an electric charge through photoelectric conversion of light and an output unit that outputs a signal generated based upon the electric charge generated in the photoelectric conversion unit; a second pixel, having a filter unit that can be switched to a light-shielding state in which light is blocked or to a transmissive state in which light is transmitted, a photoelectric conversion unit that generates an electric charge through photoelectric conversion of light having been transmitted through the filter unit and an output unit that outputs a signal generated based upon the electric charge generated in the photoelectric conversion unit; and a control unit that allows a signal to be output from the output unit of the second pixel by setting the filter unit of the second pixel in a light-shielding state after having a signal output from the output unit of the first pixel.

### BRIEF DESCRIPTION OF DRAWINGS

FIG. 1 is a block diagram showing a structure of an image capturing device according to a first embodiment.

FIG. 2 is a block diagram showing a structure of part of an image sensor according to the first embodiment.

FIG. 3 presents diagrams in reference to which the image sensor according to the first embodiment will be explained.

FIG. 4 shows diagrams in reference to which a signal readout method adopted in the image sensor according to the first embodiment will be explained.

FIG. 5 shows diagrams presenting a specific example of the signal readout method adopted in the image sensor according to the first embodiment.

FIG. 6 is a circuit diagram showing the structure adopted in a pixel in the image sensor according to the first embodiment.

FIG. 7 is a circuit diagram showing the structure adopted in part of the image sensor according to the first embodiment.

FIG. 8 is a timing chart presenting an example of an operation that may be executed in the image sensor according to the first embodiment

FIG. 9 is a circuit diagram presenting an example of a structure that may be adopted in the image sensor according to variation 1.

FIG. 10 is a circuit diagram presenting another example of a structure that may be adopted in the image sensor according to variation 1.

FIG. 11 is a circuit diagram showing the structure adopted in a pixel in the image sensor according to variation 2.

### DESCRIPTION OF EMBODIMENT

### First Embodiment

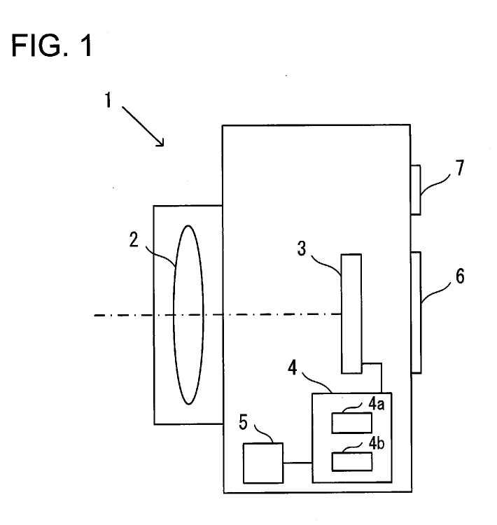

FIG. 1 is a block diagram showing a structure of an image capturing device according to a first embodiment. FIG. 1 shows an example of a structure of an electronic camera 1 (hereafter will be referred to as a camera 1) which is one example of the image capturing device. The camera 1 comprises an image capturing optical system (image forming optical system) 2, an image sensor 3, a control unit 4, a memory 5, a display unit 6 and an operation unit 7. The photographic optical system 2, which includes a plurality of lenses and an aperture, forms a subject image at the image sensor 3. It is to be noted that the photographic optical system 2 may be a detachable system that can be mounted at and dismounted from the camera 1.

The image sensor 3 may be, for instance, a CMOS image sensor. The image sensor 3 captures the subject image formed via the photographic optical system 2. At the image sensor 3, a plurality of pixels, each having a microlens, a filter unit, the transmission wavelength of which can be altered, and a photoelectric conversion unit, are disposed in a two-dimensional pattern, as will be explained in detail later. The photoelectric conversion unit may be configured with, for instance, a photodiode (PD). The image sensor 3 generates pixel signals through photoelectric conversion of light having entered therein and outputs the pixel signals thus generated to the control unit 4. The pixel signals are each generated based upon an electric charge resulting from the photoelectric conversion at the photoelectric conversion unit. As will be described in detail later, the image sensor 3 outputs still image pixel signals to be used to generate still image data, and video image pixel signals to be used to generate video image data, to the control unit 4. The term “video image” used in this context refers to an image generated based upon pixel signals read out from pixels in specific rows or columns among all the pixels through a culled read or based upon pixel signals each read out by adding signals from a plurality of pixels. In addition, a still image is an image generated based upon pixel signals individually read out from the pixels at the image sensor 3 instead of reading out pixel signals through a culled read or a summing read described above.

The memory 5 may be, for instance, a recording medium such as a memory card. Still image data, video image data and the like are recorded into the memory 5. Data are written into and read out from the memory 5 by the control unit 4. At the display unit 6, a still image is displayed based upon still image data, a video image is displayed based upon video image data, and photographic information indicating the shutter speed, the aperture value and the like, a menu screen and the like are also displayed. The operation unit 7, which includes a still image shoot button, a video shoot button, various setting switches and the like, outputs an operation signal corresponding to a given operation to the control unit 4.

The control unit 4, configured with a CPU, a ROM, a RAM and the like, controls various components of the camera 1 based upon a control program. In addition, the control unit 4 includes a video image generation unit 4a and a still image generation unit 4b. The video image generation unit 4a generates video image data by executing various types of image processing on video image pixel signals output from the image sensor 3. The still image generation unit 4b generates still image data by executing various types of image processing on still image pixel signals output from the image sensor 3. The various types of image processing include image processing of the known art such as gradation conversion processing, color interpolation processing and edge enhancement processing.

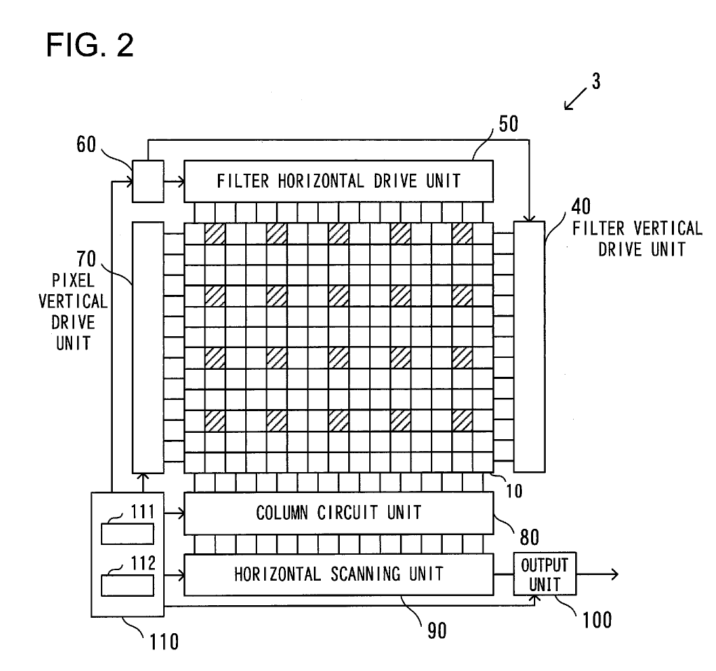

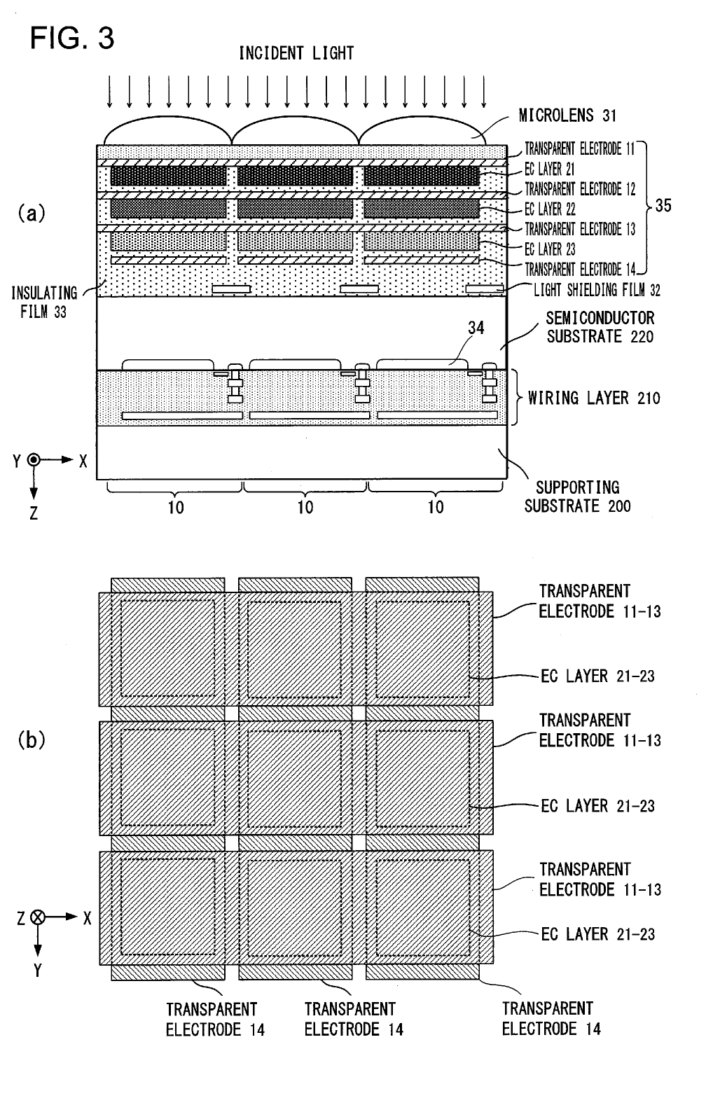

In reference to FIG. 2 and FIG. 3, the structure of the image sensor according to the first embodiment will be explained. FIG. 2 is a block diagram showing a structure of part of the image sensor 3 according to the first embodiment. FIG. 3 presents diagrams in reference to which the image sensor 3 according to the first embodiment will be explained. FIG. 3(a) is a diagram illustrating an example of a sectional structure of the image sensor 3, whereas FIG. 3(b) is a plan view illustrating an example of a layout of transparent electrodes in the filter units at the image sensor 3.

As shown in FIG. 2, the image sensor 3 includes a plurality of pixels 10, a filter vertical drive unit 40, a filter horizontal drive unit 50, a filter control unit 60, a pixel vertical drive unit 70, a column circuit unit 80, a horizontal scanning unit 90, an output unit 100 and a system control unit 110. At the image sensor 3, the pixels 10 are disposed in a two-dimensional pattern (e.g., along a row direction, i.e., along a first direction in which rows extend, and a column direction, i.e., a second direction intersecting the first direction, along which columns extend). In the example presented in FIG. 2, only 15 pixels in a horizontal direction×12 pixels in a vertical direction are shown as the pixels 10 so as to simplify the illustration. However, the image sensor 3 actually includes, for instance, several million to several hundred million pixels, or an even greater number of pixels.

As shown in FIG. 3(a), the image sensor 3 includes a semiconductor substrate 220, a wiring layer 210, a supporting substrate 200, microlenses 31 and filter units 35. The image sensor 3 as the example presented in FIG. 3(a) is configured as a backside illumination image sensor. The semiconductor substrate 220 is laminated onto the supporting substrate 200 via the wiring layer 210. The semiconductor substrate 220 is constituted with a semiconductor substrate, for instance a silicon substrate, and the supporting substrate 200 is constituted with a semiconductor substrate, a glass substrate or the like. The wiring layer 210, which includes a conductor film (metal film) and an insulating film, a plurality of wirings, vias and the like are disposed. The conductor film may be constituted of, for instance, copper or aluminum. The insulating film may be an oxide film or a nitride film. As shown in FIG. 3(a), light having passed through the photographic optical system 2 enters the image sensor primarily toward the + side of a Z axis. As the coordinate axes in the figure indicate, the direction running rightward on the drawing sheet perpendicular to the Z axis is designated as an X axis+direction and the direction running toward the viewer of the drawing, perpendicular to the Z axis and the X axis, is designated as a Y axis+direction.

A pixel 10 is structured so as to include a microlens 31, a filter unit 35, light shielding film 32 and a photoelectric conversion unit 34. The microlens 31 condenses light having entered therein onto the photoelectric conversion unit 34. The light shielding film 32, disposed at a boundary between pixels 10 disposed adjacent to each other, minimize light leakage from one pixel to the other.

The filter unit 35 includes electro-chromic (hereafter will be referred to as EC) layers 21, 22 and 23 and transparent electrodes 11, 12, 13 and 14, laminated in sequence, starting on the side where the microlens 31 is present, toward the semiconductor substrate 220. The EC layers 21 through 23 are formed by using an electro-chromic material such as a metal oxide. The transparent electrodes 11 through 14 are formed by, for instance, ITO (indium tin oxide). An insulating film 33 is disposed in the areas between the EC layer 21 and the transparent electrode 12, between the EC layer 22 and the transparent electrode 13, and between the EC layer 23 and the transparent electrode 14. In addition, an electrolyte layer (electrolyte film) (not shown) is disposed in the filter unit 35.

The transparent electrodes 11 are disposed, each in correspondence to a plurality of EC layers 21 that are disposed one after another along the X direction, i.e., the row direction, so as to cover the surfaces of the plurality of EC layers 21 located on one side, as is clearly shown in FIG. 3(b). In the example presented in FIG. 2, the pixels 10 are arrayed in twelve rows and thus, twelve transparent electrodes 11 are disposed in parallel to one another. Transparent electrodes 12 and transparent electrodes 13 are also disposed in much the same way as the transparent electrodes 11, so as to respectively cover the surfaces of the plurality of EC layers 22 and the surfaces of the plurality of EC layers 23 disposed one after another along the X direction on one side thereof.

The transparent electrode 14, which is a common electrode used in conjunction with three EC layers 21, 22 and 23, is disposed on the side where the other surface of the EC layer 23 is located. Common transparent electrodes 14 are disposed, each in correspondence to the plurality of sets of EC layers 23 that are disposed one after another to extend along the Y direction, i.e., the column direction, along the plurality of EC layers 23, disposed one after another to extend along the column direction as is clearly shown in FIG. 3(b). In the example presented in FIG. 2, the pixels 10 are arrayed over 15 columns, and thus, 15 common transparent electrodes 14 are disposed parallel to one another.

The transparent electrodes 11 through 13 and the common transparent electrodes 14 are electrodes disposed in a matrix pattern (mesh pattern) in relation to the EC layers 21, 22 and 23. The transparent electrodes 11 through 13 are connected to the filter vertical drive unit 40, whereas the common transparent electrodes 14 are connected to the filter horizontal drive unit 50. Thus, active matrix drive that enables drive control for the EC layers 21, 22 and 23 can be executed by using the electrodes disposed in the matrix pattern in the present embodiment.

The EC layer 21 produces B (blue) color through an oxidation-reduction reaction induced as a drive signal is provided via the transparent electrode 11 and common transparent electrode 14. This means that light in a wavelength range corresponding to B (blue) in the incident light is transmitted through the EC layer 21 as a drive signal is provided thereto. The EC layer 22 produces G (green) color through an oxidation-reduction reaction induced as a drive signal is provided via the transparent electrode 12 and common transparent electrode 14. This means that light in a wavelength range corresponding to G (green) in the incident light is transmitted through the EC layer 22 as a drive signal is provided thereto. The EC layer 23 produces R (red) color through an oxidation-reduction reaction induced as a drive signal is provided via the transparent electrode 13 and common transparent electrode 14. This means that light in a wavelength range corresponding to R (red) in the incident light is transmitted through the EC layer 23 as a drive signal is provided thereto. At each of the EC layers 21, 22 and 23, the color produced as described above is sustained over a predetermined length of time even when the drive signal is no longer provided thereto, whereas each of the EC layers achieve a transparent (decoloration) state, in which light in the entire wavelength range in the light having entered the filter unit 35 is transmitted through them when a reset signal is provided thereto.

As described above, the plurality of filter units 35 are each configured with three filters, i.e., the EC layer 21 that produces B (blue) color, the EC layer 22 that produces G (green) color and the EC layer 23 that produces R (red) color. This means that light primarily in a specific wavelength range among the wavelength ranges corresponding to W (white), BK (black), R (red), G (green) and B (blue) can be allowed to be transmitted through the filter unit 35 by selecting a specific combination of transmission wavelengths for the EC layers 21 through 23.

When no drive signal is provided to any of the three types of EC layers 21, 22 and 23, a wavelength range of light transmitted through three layers of the EC corresponds to W (white). When a drive signal is provided to all three EC layers, 21, 22 and 23, a wavelength range of light transmitted through three layers of the EC corresponds to BK (black). When a drive signal is provided to the EC layer 21 alone, to the EC layer 22 alone or to the EC layer 23 alone, a wavelength range of light transmitted through three layers of the EC corresponds to B (blue), G (green) or R (red). Namely, a filter unit 35 becomes a B (blue) color filter when a drive signal is provided to the EC layer 21 thereof alone, becomes a G (green) color filter when a drive signal is provided to the EC layer 22 thereof alone and becomes an R (red) color filter when a drive signal is provided to the EC layer 23 thereof alone.

As will be explained later, each of the filter units 35 is controlled during a video shooting operation or a still image capturing operation so that it functions as a B (blue) color filter, a G (green) color filter or an R (red) color filter. Pixels with R color filters (hereafter will be referred to as R pixels), pixels with G color filters (hereafter will be referred to as G pixels) and pixels with B color filters (hereafter will be referred to as B pixels) may form, for instance, a Bayer array pattern.

In addition, in response to a still image capturing instruction issued while video shooting is in progress, the filter units 35 at some specific pixels are controlled so that they each function as a B (blue) color filter, a G (green) color filter or an R (red) color filter, while the filter units 35 at the remaining pixels are controlled so as to correspond to BK (black).

The filter control unit 60 in FIG. 2 sets (adjusts) the transmission wavelength for each filter unit 35 by controlling signals input to the filter unit 35 from the filter vertical drive unit 40 and the filter horizontal drive unit 50. The filter vertical drive unit 40 selects a specific row among a plurality of rows in which filter units 35 are disposed, i.e., it selects a specific transparent electrode among the plurality of transparent electrodes 11 through 13 and provides a drive signal to the selected transparent electrode. The filter horizontal drive unit 50 selects a specific column in which filter units 35 are disposed, i.e., it selects a specific transparent electrode among the plurality of common transparent electrodes 14, and provides a drive signal to the selected common transparent electrode. As a result, an EC layer corresponding to both the transparent electrode among the transparent electrodes 11 through 13 selected by the filter vertical drive unit 40 and the common transparent electrode 14 selected by the filter horizontal drive unit 50 produces a color.

For instance, the filter horizontal drive unit 50 may select the common transparent electrode 14 located at the right end, among the three common transparent electrodes 14 in FIG. 3(b), and provide a drive signal to the selected common transparent electrode 14, and the filter vertical drive unit 40 may select the transparent electrode 11 located at the upper end in FIG. 3(b) among the nine transparent electrodes 11 through 13 and provide a drive signal thereto. In such a case, the EC layer 21 located at the upper right end position will produce a color. In addition, if the filter horizontal drive unit 50 selects the same common transparent electrode 14 and provides a drive signal thereto and the filter vertical drive unit 40 selects the transparent electrode 12 located at the upper end in FIG. 3(b) and provides a drive signal thereto, the EC layer 22 at the upper right end produces a color. If the filter horizontal drive unit 50 selects the same common transparent electrode 14 and provides a drive signal thereto and the filter vertical drive unit 40 selects the transparent electrode 13 located at the upper end in FIG. 3(b) and provides a drive signal thereto, the EC layer 23 at the upper right end produces a color.

The system control unit 110 in FIG. 2 controls the filter control unit 60, the pixel vertical drive unit 70, the column circuit unit 80, the horizontal scanning unit 90 and the output unit 100 based upon signals provided from the control unit 4 in the electronic camera 1. In addition, the system control unit 110 includes a video image readout unit 111 and a still image readout unit 112.

When a video shooting instruction is issued in response to a user operation performed at a video shoot button, the video image readout unit 111 selects pixels (hereafter will be referred to as video pixels) to be used for purposes of video image data generation, among all the pixels 10 disposed at the image sensor 3, and reads out pixel signals from the selected pixels. Namely, the video image readout unit 111 specifies video pixels from which pixel signals are to be read out for the video shooting operation, among all the pixels 10. The video image readout unit 111 selects pixels by skipping pixels in specific rows or columns among all the pixels 10 and reads out pixel signals from the selected video pixels. In other words, the video image readout unit 111 executes control under which a video shooting operation is executed at a specific frame rate through a culled read. The video image readout unit 111 may select, for instance, the plurality of shaded pixels 10 in FIG. 2 as video pixels to read out the pixel signals from them. In the example presented in FIG. 2, video pixels are selected at a rate of one pixel out of every nine pixels. To describe this in more specific detail, all the pixels are divided into blocks made up of 3 pixels×3 pixels=9 pixels and pixels taking matching positions within the blocks are selected as video pixels. The video pixels selected as described above also form a Bayer array pattern.

In case a still image capturing instruction is issued in response to a user operation performed at a still image capture button, the still image readout unit 112 selects pixels (hereafter will be referred to as still image pixels) to be used for purposes of still image data generation, and reads out pixel signals from the selected pixels. The still image readout unit 112 in the present embodiment selects all the pixels 10 at the image sensor 3 as still image pixels and reads out pixel signals from all the pixels 10.

In addition, in case the still image capture button is operated while a video shooting operation is in progress and thus a video shooting instruction and a still image capturing instruction are both issued, the still image readout unit 112 executes control for capturing a still image during the video shooting operation. More specifically, while the still image readout unit 112 selects all the pixels 10 as still image pixels, it reads out pixel signals from the still image pixels separately over a plurality of frames constituting the video image instead of reading out the pixel signals from all the still image pixels at once. For instance, in case that the still image readout unit 112 reads out still image pixel signals for one frame from two video image frames, it will read out pixel signals at some of the pixels 10 (e.g., half of the pixels) corresponding to one of two frames of the video image and will read out the pixel signals at the remaining pixels corresponding to the other of two frames of the video image. The still image readout unit 112 individually reads out the pixel signals from the still image pixels over the plurality of different frames constituting the video image when the pixel signals are read out from the video pixels for the corresponding frames.

The pixel vertical drive unit 70 provides control signals such as a signal TX, a signal RST and a signal SEL which will be described in detail later, to the various pixels 10, based upon signals provided from the video image readout unit 111 and the still image readout 112, so as to control operations of the individual pixels 10.

The column circuit unit 80, configured so as to include a plurality of analog/digital conversion units (A/D conversion units), converts signals, which are input thereto via vertical signal lines 30 to be explained later from the individual pixels 10, to digital signals and outputs the digital signals resulting from the conversion to the horizontal scanning unit 90. The horizontal scanning unit 90 sequentially outputs the signals, having been output from the column circuit unit 80, to the output unit 100. The output unit 100, which includes a signal processing unit (not shown), executes signal processing such as correlated double sampling and signal level correction processing and outputs the signals having undergone the signal processing to the control unit 4 in the electronic camera 1. The output unit 100, having an input/output circuit and the like supporting a high-speed interface such as LVDS and SLVS, is able to transmit the signals to the control unit 4 at high speed.

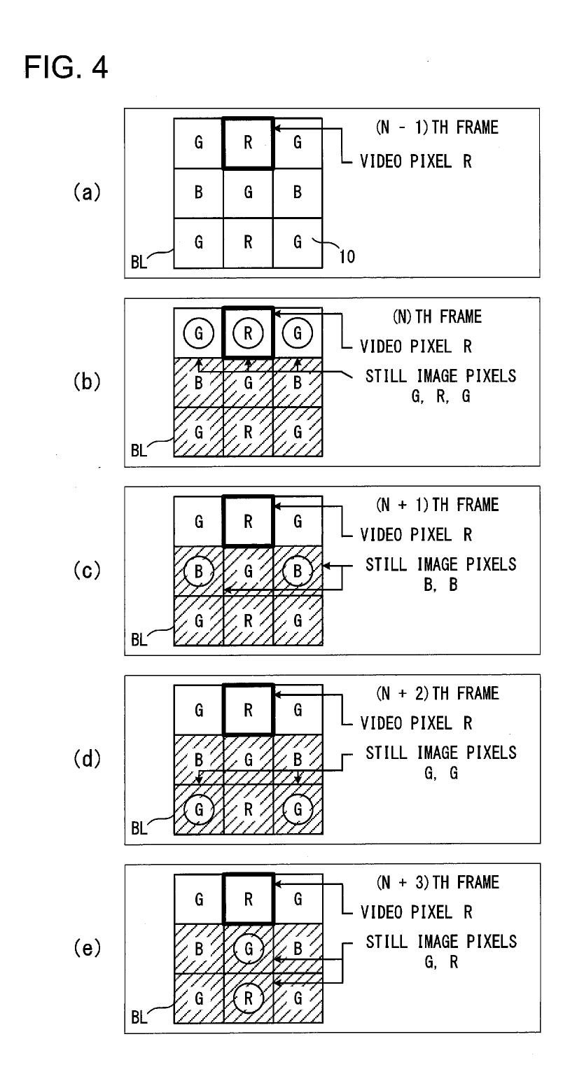

Next, in reference to FIG. 4, the operation executed in the image sensor 3 in case a still image capturing operation is executed concurrently with a video shooting operation will be explained. FIG. 4(a) shows a video pixel from which a pixel signal is read out by the video image readout unit 111 for an (N−1)th frame during a video shooting operation. FIG. 4(b) shows a video pixel from which a pixel signal is read out by the video image readout unit 111 and still image pixels from which pixel signals are read out by the still image readout unit 112 for an (N)th frame during the video shooting operation. FIGS. 4(c) through 4(e) respectively show a video pixel from which a image pixel signal is read out by the video image readout unit 111 and still image pixels from which pixel signals are read out by the still image readout unit 112 for an (N+1)th frame, an (N+2)th frame and an (N+3)th frame.

FIG. 4 shows a single block BL among blocks BL formed by dividing all the pixels at the image sensor 3 into blocks, each made up with 3×3 pixels=9 pixels. The pixel 10 inside the bold-line frame in the block BL is the video pixel (an R pixel in the example presented in FIG. 4) from which a pixel signal is read out by the video image readout unit 111. In addition, pixels, that circles are attached inside, are still image pixels from which pixel signals are read out by the still image readout unit 112.

During a video shooting operation executed at a specific frame rate, the filter units 35 at various pixels are each controlled to function as a B (blue) color filter, a G (green) color filter or an R (red) color filter. This means that while shooting the (N−1)th frame during the video shooting operation shown in FIG. 4(a), the pixels 10 at the image sensor 3 are controlled so as to function as G pixels, R pixels and B pixels set in a Bayer array. The video image readout unit 111 selects pixels assuming matching positions in the respective blocks BL (the R pixel inside the bold-line frame at the first row/second column position within the block BL in the example presented in the figure) as video pixels and reads out pixel signals from the selected video pixels. The video image readout unit 111 reads out pixel signals from the G pixels disposed at matching positions in the blocks adjacent to the block BL in the figure along the left/right direction and along the up/down direction and reads out pixel signals from B pixels disposed at matching positions in the blocks adjacent to the block BL in the figure along the diagonal directions. The video image readout unit 111 thus executes a 1/9-rate culled read from R pixels, G pixels and B pixels forming a Bayer array pattern.

The pixel signals from the video pixels thus read out are used to generate video image data at the video image generation unit 4a in FIG. 1.

As a still image capturing instruction is issued in response to an operation performed at the still image capture button while such a video shooting operation is in progress, the video image readout unit 111 selects the R pixel inside the bold-line frame at the first row/second column position as a video pixel, as shown in FIG. 4(b), as it did for the (N−1)th frame, and reads out a pixel signal from the video pixel. At the same time, the still image readout unit 112 reads out pixel signals from the three still image pixels that the circles are attached inside, located in the first row within the block BL, i.e., from the G pixel, the R pixel and the B pixel. In other words, the R pixel, that is inside the bold-line frame and the circle is attached inside, at the first row/second column position is selected both as a video pixel and a still image pixel by the video image readout unit 111 and the still image readout unit 112, and the pixel signal is read out from the R pixel for the (N)th frame.

Pixel signals from the video pixels thus read out are used to generate video image data at the video image generation unit 4a in FIG. 1. In addition, pixel signals read out from the still image pixels are temporarily stored into the memory 5 in FIG. 1 or a memory (not shown) built into the control unit 4.

For the (N)th frame of the video image illustrated in FIG. 4 (b), the filter control unit 60 shifts the filter units 35 at the shaded pixels into a BK (black) state, i.e., into a light-shielding state, in synchronization with the readout of the pixel signals from the video pixel and the still image pixels, or before and after the readout. To describe this in further detail, the filter units 35 at the shaded pixels other than the still image pixels from which pixel signals are read out by the still image readout unit 112, are controlled so as to assume a light-shielding state for the (N)th frame.

At a pixel, the filter unit 35 of which is in a light-shielding state, light advancing toward the photoelectric conversion unit 34 is blocked by the filter unit 35, and thus, an electric charge resulting from the photoelectric conversion is held at the photoelectric conversion unit 34. Namely, the photoelectric conversion unit 34 in a pixel in a light-shielding state holds an electric charge having resulted from the photoelectric conversion and having accumulated before the filter unit 35 entered the light-shielding state. Thus, pixel signals at some pixels, among all the pixels, are read out as pixel signals from video pixels and still image pixels for the (N)th frame. In addition, electric charges having accumulated in the photoelectric conversion units 34 in the remaining pixels in the light-shielding state, among all the pixels, are held until the subsequent readouts for the (N+1)th frame, the (N+2)th frame and the (N+3)th frame.

For the (N+1)th frame of the video image shown in FIG. 4(c), the video image readout unit 111 selects the R pixel inside the bold-line frame at the first row/second column position within the block BL as a video pixel, as it did for the (N)th frame and reads out a pixel signal from the video pixel. The still image readout unit 112 reads out pixel signals, generated based upon the electric charges held in the respective photoelectric conversion units 34 at two still image pixels, i.e., the two B pixels in a light-shielding state, that the circles are attached inside, taking the second row/first column position and the second row/third column position inside the block BL. In other words, for the (N+1)th frame of the video image, the video image readout unit 111 reads out a new pixel signal generated through exposure, from the R pixel inside the bold-line frame and the still image readout unit 112 reads out pixel signals corresponding to the electric charges held in the still image pixels.

Pixel signals from the video pixels for the (N+1)th frame thus read out are used to generate video image data at the video image generation unit 4a in FIG. 1. In addition, pixel signals read out from the still image pixels are temporarily stored into the memory 5 in FIG. 1 or a memory (not shown) built into the control unit 4.

For the (N+2)th frame of the video image shown in FIG. 4(d), the video image readout unit 111 selects the R pixel inside the bold-line frame at the first row/second column position within the block BL as a video pixel, as it did for the (N)th frame and reads out a pixel signal from the video pixel. The still image readout unit 112 reads out pixel signals, generated based upon the electric charges held in the respective photoelectric conversion units 34 at two still image pixels, i.e., the two G pixels in a light-shielding state, that the circles are attached inside, taking the third row/first column position and the third row/third column position inside the block BL. In other words, for the (N+2)th frame of the video image, the video image readout unit 111 reads out a new pixel signal generated through exposure, from the R pixel inside the bold-line frame and the still image readout unit 112 reads out pixel signals corresponding to the electric charges held in the still image pixels.

Pixel signals from the video pixels for the (N+2)th frame thus read out are used to generate video image data at the video image generation unit 4a in FIG. 1. In addition, pixel signals read out from the still image pixels are temporarily stored into the memory 5 in FIG. 1 or a memory (not shown) built into the control unit 4.

For the (N+3)th frame of the video image shown in FIG. 4(e), the video image readout unit 111 selects the R pixel inside the bold-line frame at the first row/second column position within the block BL as a video pixel, as it did for the (N)th frame, and reads out a pixel signal from the video pixel. The still image readout unit 112 reads out pixel signals, generated based upon the electric charges held in the respective photoelectric conversion units 34 at two still image pixels, i.e., a G pixel in a light-shielding state, that a circle is attached inside, taking the second row/second column position and an R pixel in a light-shielding state, that a circle is attached inside, taking a position at the third row/second column position, within the block BL. In other words, for the (N+3)th frame of the video image, the video image readout unit 111 reads out a new pixel signal generated through exposure, from the R pixel inside the bold-line frame and the still image readout unit 112 reads out pixel signals corresponding to the electric charges held in the still image pixels.

Pixel signals from the video pixels for the (N+3)th frame thus read out are used to generate video image data at the video image generation unit 4a in FIG. 1. In addition, pixel signals read out from the still image pixels are temporarily stored into the memory 5 in FIG. 1 or a memory (not shown) built into the control unit 4.

The pixel signals having been read out as pixel signals from the still image pixels and having been stored in the memory on a temporary basis during the period of time elapsing from the capture of the (N)th frame through the capture of the (N+3)th frame are used by the still image generation unit 4b for generation of still image data.

As described above, the image sensor 3 reads out pixel signals generated based upon electric charges resulting from photoelectric conversion from the video pixels for the (N)th through (N+3)th frames during the video shooting operation. In addition, the image sensor 3 reads out pixel signals corresponding to electric charges held in the photoelectric conversion units 34 at different pixels 10 among the pixels 10 designated as still image pixels, for each of the four frames, i.e., the (N)th through (N+3)th frames.

The video image generation unit 4a in the image sensor 3 generates video image data based upon the video image pixel signals sequentially output in correspondence to the frames constituting the video image being shot. The still image generation unit 4b in the image sensor 3 generates still image data based upon the still image pixel signals output over a plurality of frames. More specifically, the still image generation unit 4b generates still image data with the pixel signals from all the pixels by combining still image pixel signals output in correspondence to individual frames.

A video shooting operation and a still image capturing operation can be executed concurrently at the image sensor 3 in the present embodiment by reading out still image pixel signals over a plurality of separate frames. In addition, since pixel signals are read out from a uniform number of pixels in correspondence to different frames, the pixel signals at all the still image pixels can be read out at the image sensor 3 while preventing any reduction in the frame rate for the video shooting operation. Namely, video image data achieving high temporal resolution can be generated. In addition, since still image data can be generated by reading out the pixel signals from all the pixels, still image data achieving high spatial resolution can be generated. Furthermore, the image sensor 3 is able to generate still image data by using pixel signals generated based upon electric charges resulting from photoelectric conversion executed with uniform timing at all the pixels. Consequently, the image quality of a still image of, for instance, a moving subject, can be improved.

In addition, the image sensor 3 in the present embodiment sets a pixel 10 in a light-shielding state by controlling its filter unit 35 so as to allow an electric charge generated through photoelectric conversion to be held in the photoelectric conversion unit 34. This means that the photoelectric conversion unit 34 is made to function as a storage unit for storing a signal (electric charge). As a result, the area of the image sensor can be reduced compared to the area required by an image sensor that includes separate storage elements each disposed in correspondence to one of the pixels. Moreover, the area of the photoelectric conversion unit 34 does not need to become reduced due to the presence of a separate storage element.

It is to be noted that pixel signals may be read out from still image pixels over a smaller number of frames or a greater number of frames than four. In addition, while all the pixels are selected as still image pixels and pixel signals are read out from all the pixels in the present embodiment, only some of the pixels at the image sensor 3 may be selected and pixel signals may be read out from the selected pixels provided that the number of pixels disposed at the image sensor 3 is extremely large. In such a case, the video pixel inside the bold-line frame in FIG. 4 may be used exclusively for video image generation and the remaining pixels designated as still image pixels may all be set in a light-shielding state.

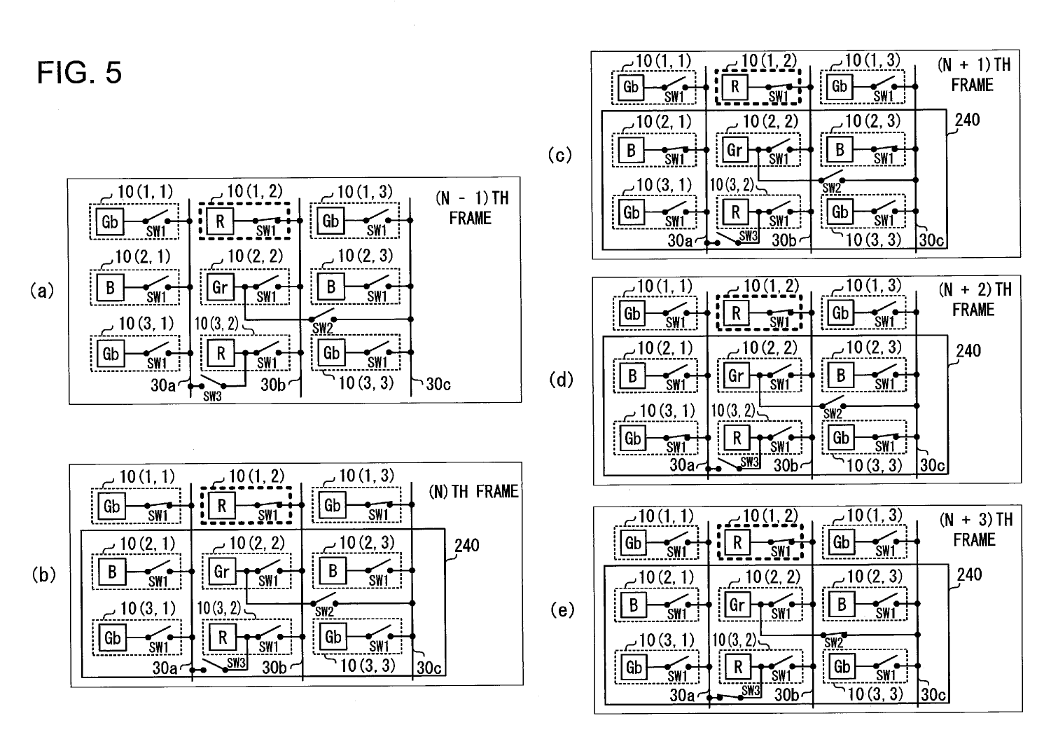

FIG. 5 presents diagrams in reference to which a specific example of a method for reading out signals at the image sensor 3 according to the first embodiment will be explained. FIGS. 5(a) through 5(e) present an example in which pixel signals are read out from a video pixel and still image pixels in correspondence to frames, i.e., the (N−1)th frame through the (N+3)th frame, like the case that shown in FIGS. 4(a) through 4(e), captured during a video shooting operation. The following is an explanation of a specific example of a method for reading out pixel signals, given in reference to FIG. 5.

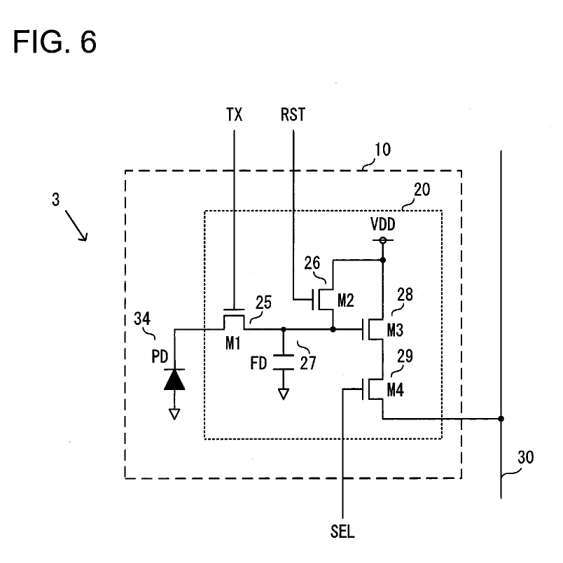

As shown in FIG. 5, vertical signal lines 30 (vertical signal line 30a through vertical signal line 30c) are disposed each in correspondence to a column made up with a plurality of pixels 10 disposed one after another along the second direction in which the columns extend, i.e. along the longitudinal direction at the image sensor 3. The pixels 10 each include a switch SW1 (indicated with a reference sign M4 in FIG. 6). In addition, the image sensor 3 includes a switch SW2 that connects the pixel 10 disposed at a coordinate point (2, 2) with the vertical signal line 30c and a switch SW3 that connects the pixel 10 disposed at a coordinate point (3, 2) with the vertical signal line 30a. The pixel signal from a video pixel is read out via the vertical signal line 30b alone at all times, in correspondence to the various frames captured through the video shooting operation. To describe this in further detail, the video pixel is a pixel that is not culled either along the row direction or along the column direction, among all the pixels. This means that the vertical signal line via which the pixel signal at the video pixel is read out is the vertical signal line connected with the video pixel, i.e., a specific vertical signal line among the vertical signal lines.

Accordingly, the image sensor 3 reads out pixel signals at the still image pixels via the vertical signal lines 30a and 30c, to which the pixel signal from the video pixel is not output, in correspondence to the individual frames over which the video shooting operation is executed. As a result, the image sensor 3 is able to concurrently read out pixel signals for video image generation and read out pixel signals for still image generation. The following is a detailed explanation.

For the (N−1)th frame shown in FIG. 5(a), the switch SW1 in the pixel 10 disposed at a coordinate point (1, 2) enters an ON state. The video pixel at the coordinate point (1, 2) outputs a pixel signal to the vertical signal line 30b. The switches SW1 in the other pixels, the switch SW2 and the switch SW3 are in an OFF state.

For the (N)th frame shown in FIG. 5(b), the switches SW1 in the pixels disposed at coordinate points (1, 1), (1, 2) and (1, 3) enter an ON state. The video pixel at the coordinate point (1, 2) outputs a pixel signal generated based upon an electric charge resulting from photoelectric conversion to the vertical signal line 30b. It is to be noted that the pixel signal at the video pixel read out for the (N)th frame is used both as a video image pixel signal and as a still image pixel signal. In addition, the still image pixel disposed at the coordinate point (1, 1) outputs a pixel signal generated based upon an electric charge resulting from photoelectric conversion to the vertical signal line 30a. Moreover, the still image pixel disposed at the coordinate point (1, 3) outputs a pixel signal generated based upon an electric charge resulting from photoelectric conversion to the vertical signal line 30c. For the (N)th frame, the pixels other than the readout target pixels for the (N)th frame are set in a light-shielding state at the image sensor 3. Namely, at the pixels 10 present in an area 240 in FIG. 5, which are set in a light-shielding state, electric charges generated through photoelectric conversion are accumulated (held) in the respective photoelectric conversion units 34.

For the (N+1)th frame shown in FIG. 5(c), the switches SW1 in the pixels disposed at coordinate points (1, 2), (2, 1) and (2, 3) enter an ON state. The video pixel outputs a pixel signal generated based upon an electric charge resulting from photoelectric conversion to the vertical signal line 30b. The still image pixels at the coordinate points (2, 1) and (2, 3) output pixel signals generated based upon held in the corresponding photoelectric conversion units 34 respectively to the vertical signal lines 30a and 30c.

For the (N+2)th frame shown in FIG. 5(d), the switches SW1 in the pixels disposed at coordinate points (1, 2), (3, 1) and (3, 3) enter an ON state. The video pixel outputs a pixel signal generated based upon an electric charge resulting from photoelectric conversion to the vertical signal line 30b. The still image pixels at the coordinate points (3, 1) and (3, 3) output pixel signals generated based upon electric charges held in the corresponding photoelectric conversion units 34 to the vertical signal lines 30a and 30c respectively.

For the (N+3)th frame, the video pixel at the coordinate point (1, 2), with its switch SW set in an ON state, outputs a pixel signal generated based upon an electric charge resulting from photoelectric conversion, to the vertical signal line 30b. In addition, as the switch SW2 enters an ON state, the still image pixel at the coordinate point (2, 2) outputs a pixel signal, generated based upon an electric charge held in the photoelectric conversion unit 34, to the vertical signal line 30c. As the switch SW3 enters an ON state, the still image pixel at the coordinate point (3, 2) outputs a pixel signal, generated based upon an electric charge held in the photoelectric conversion unit 34, to the vertical signal line 30a.

At the image sensor 3 achieved in the present embodiment, a pixel signal is read out from a video pixel selected by culling pixels along the row direction and the column direction among all the pixels. As a result, pixel signals at video pixels can be read out at high speed. This, in turn, makes it possible to improve the frame rate for a video shooting operation at the image sensor 3. In addition, a video image pixel signal is read out via the corresponding vertical signal line 30b and still image pixel signals are read out via the vertical signal lines 30a and 30c, which are not used for video image pixel signal readout at the image sensor 3. Thus, video image pixel signals and still image pixel signals can be read out simultaneously in correspondence to each of the (N)th through the (N+3)th frames captured through the video shooting operation. Consequently, even in case a still image capturing operation is executed while a video shooting operation is in progress at the image sensor 3, the frame rate for the video shooting operation does not become lowered.

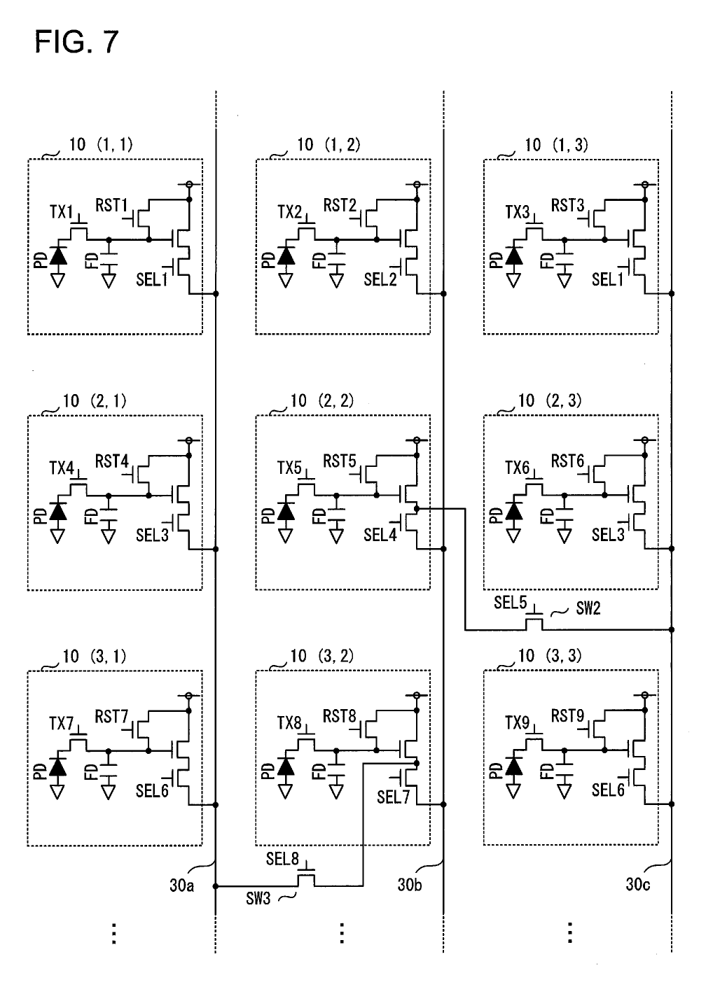

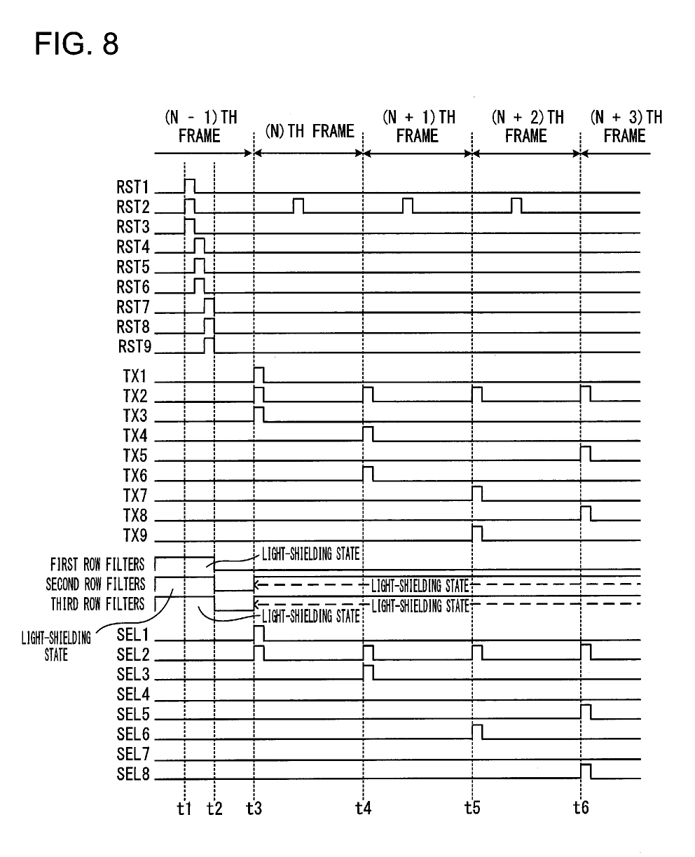

In reference to FIGS. 6 through 8, the circuit structure adopted in the image sensor 3 and operations executed in the image sensor 3 according to the first embodiment will be explained. FIG. 6 is a circuit diagram showing the structure of a pixel 10 in the image sensor 3 according to the first embodiment. FIG. 7 is a circuit diagram showing the structure assumed in part of the image sensor 3 according to the first embodiment. FIG. 8 is a timing chart pertaining to an example of an operation that may be executed in the image sensor 3 according to the first embodiment.

As shown in FIG. 6, the pixel 10 includes the photoelectric conversion unit 34 and a readout unit 20. The photoelectric conversion unit 34 has a function of converting light having entered therein to an electric charge and accumulating the electric charge resulting from the photoelectric conversion therein. The readout unit 20 includes a transfer unit 25, a reset unit 26, a floating diffusion 27, an amplifier unit 28 and a selection unit 29.

The transfer unit 25 transfers the electric charge resulting from the photoelectric conversion executed at the photoelectric conversion unit 34 to the floating diffusion 27 under control executed based upon a signal TX. Namely, the transfer unit 25 forms an electric charge transfer path between the photoelectric conversion unit 34 and the floating diffusion 27. A capacitance FD at the floating diffusion 27 accumulates the electric charge. The amplifier unit 28 amplifies a pixel signal generated based upon the electric charge accumulated at the capacitance FD and outputs the amplified signal as a pixel signal. In the example presented in FIG. 6, the amplifier unit 28 is configured with a transistor M3, a drain terminal, a gate terminal and a source terminal of which are respectively connected to a source VDD, the floating diffusion 27 and the selection unit 29. The source terminal of the amplifier unit 28 is connected to a vertical signal line 30 via the selection unit 29. The amplifier unit 28 functions as part of a source follower circuit that uses a current source (not shown) connected to the vertical signal line 30 as a load current source.

The reset unit 26, which is controlled based upon a signal RST, resets the electric charge at the capacitance FD and resets the potential at the floating diffusion 27 to a reset potential (reference potential). The selection unit 29, which is controlled based upon a signal SEL, outputs the pixel signal provided from the amplifier unit 28 to the vertical signal line 30. The transfer unit 25, the reset unit 26 and the selection unit 29 may be respectively configured with, for instance, a transistor M1, a transistor M2 and a transistor M4. The transistor M4 is the switch SW1 having been explained earlier in reference to FIG. 5. The amplifier unit 28 and the selection unit 29 configure an output unit that outputs a signal generated based upon the electric charge generated in the photoelectric conversion unit 34.

As shown in FIG. 7, the image sensor 3 includes a plurality of pixels 10 disposed in a matrix pattern and vertical signal lines 30a through 30c as has been explained earlier. The signal TX, the signal RST and the signal SEL input to each pixel 10 are provided by the pixel vertical drive unit 70 (see FIG. 2). In addition, on/off control for the switch SW2 and the switch SW3 is executed with control signals provided thereto from the pixel vertical drive unit 70. It is to be noted that the illustration of the example presented in FIG. 7 shows nine pixels, i.e., from the pixel 10 (1, 1) through the pixel 10 (3, 3), as do FIG. 4 and FIG. 5, for purposes of simplification.

Time points are indicated along the horizontal axis in the timing chart presented in FIG. 8. In addition, in the chart in FIG. 8, a transistor or a switch, to which a control signal at high level (e.g., at the source potential) is input, enters an ON state and a transistor or a switch, to which a control signal at low level (e.g., at the ground potential) is input, enters an OFF state.

During a period of time elapsing between a time point t1 and a time point t2, signals RST1 through RST9 sequentially shift to high level, thereby turning on the transistors M2 constituting the reset units 26 and setting the potential at the floating diffusions 27 to the reset potential at the pixel 10 (1, 1) through the pixel 10 (3, 3). In addition, at the time point t2, the filter units 35 at the pixel 10 (1, 1) through the pixel 10 (3, 3) are controlled so that the filter units 35 form a Bayer array pattern as has been explained in reference to FIG. 5(a).

At a time point t3, signals TX1 through TX3 shift to high level, thereby turning on the transistors M1 constituting the transfer units 25 in the pixel 10 (1, 1) through the pixel 10 (1, 3). As a result, electric charges having resulted from photoelectric conversion at the PDs during the time period elapsing between the time point t2 and the time point t3 are transferred to the capacitances FD at the respective floating diffusions 27. In addition, at the time point t3, a signal SEL1 and a signal SEL2 shift to high level, and thus, the pixel signals at the pixel 10 (1, 1) through the pixel 10 (1, 3) are respectively output to the vertical signal line 30a through the vertical signal line 30c via the amplifier units 28 and the selection units 29. At the time point t3, the transmission wavelength is controlled for the filter units 35 in the pixel 10 (2, 1) through the pixel 10 (3, 3) so as to set the pixel 10 (2, 1) through the pixel 10 (3, 3) in a light-shielding state, as well. The PDs in the pixel 10 (2, 1) through the pixel 10 (3, 3) accumulate (hold) electric charges generated through photoelectric conversion.

At a time point t4, signals TX2, TX4 and TX6 shift to high level, thereby turning on the transistors M1 constituting the transfer units 25 in the pixel 10 (1, 2), the pixel 10 (2, 1) and the pixel 10 (2, 3). As a result, a new electric charge resulting from photoelectric conversion is transferred to the capacitance FD in the floating diffusion 27 in the pixel 10 (1, 2). In addition, electric charges held at the PDs are transferred to the capacitances FD at the respective floating diffusions 27 in the pixel 10 (2, 1) and the pixel 10 (2, 3). Furthermore, since the signal SEL2 shifts to high level, the pixel signal at the pixel 10 (1, 2) is output to the vertical signal line 30b at the time point t4. Moreover, at the time point t4, a signal SEL3 shifts to high level and thus, the pixel signal at the pixel 10 (2, 1) is output to the vertical signal line 30a and the pixel signal at the pixel 10 (2, 3) is output to the vertical signal line 30c.

At a time point t5, signals TX2, TX7 and TX9 shift to high level, thereby turning on the transistors M1 constituting the transfer units 25 in the pixel 10 (1, 2), the pixel 10 (3, 1) and the pixel 10 (3, 3). As a result, a new electric charge resulting from photoelectric conversion is transferred to the capacitance FD in the floating diffusion 27 in the pixel 10 (1, 2). In addition, electric charges held at the PDs are transferred to the capacitances FD at the respective floating diffusions 27 in the pixel 10 (3, 1) and the pixel 10 (3, 3). Furthermore, since the signal SEL2 shifts to high level, the pixel signal at the pixel 10 (1, 2) is output to the vertical signal line 30b at the time point t5. Moreover, at the time point t5, a signal SEL6 shifts to high level and thus, the pixel signal at the pixel 10 (3, 1) is output to the vertical signal line 30a and the pixel signal at the pixel 10 (3, 3) is output to the vertical signal line 30c.

At a time point t6, signals TX2, TX5 and TX8 shift to high level, thereby turning on the transistors M1 constituting the transfer units 25 in the pixel 10 (1, 2), the pixel 10 (2, 2) and the pixel 10 (3, 2). As a result, a new electric charge resulting from photoelectric conversion is transferred to the capacitance FD in the floating diffusion 27 in the pixel 10 (1, 2). In addition, electric charges held at the PDs are transferred to the capacitances FD at the respective floating diffusions 27 in the pixel 10 (2, 2) and the pixel 10 (3, 2). Furthermore, since the signal SEL2 shifts to high level, the pixel signal at the pixel 10 (1, 2) is output to the vertical signal line 30b at the time point t6. Moreover, at the time point t6, a signal SEL5 shifts to high level and thus, the pixel signal at the pixel 10 (2, 2) is output to the vertical signal line 30c via the switch SW2. At the time point t6, a signal SEL8 shifts to high level and, as a result, the pixel signal at the pixel 10 (3, 2) is output to the vertical signal line 30a via the switch SW3.

The pixel signals output to the vertical signal lines 30a through 30c in correspondence to each frame are output via the column circuit unit 80, the horizontal scanning unit 90 and the output unit 100 shown in FIG. 2, to the control unit 4 in the electronic camera 1. The video image generation unit 4a in the control unit 4 generates video image data based upon the video image pixel signals sequentially output in correspondence to each of the frames. In addition, the still image generation unit 4b in the control unit 4 generates still image data based upon still image pixel signals output over a plurality of frames.

The following advantages effects are achieved through the embodiment described above.

(1) The image sensor 3 comprises a first pixel, having a photoelectric conversion unit 34 that generates an electric charge through photoelectric conversion of incident light having entered therein and accumulates the electric charge, which outputs a signal generated based upon the electric charge generated at the photoelectric conversion unit 34 thereof, second pixels, each having a filter unit 35 that switches between a light-shielding state in which incident light is blocked and a transmissive state in which incident light is transmitted and a photoelectric conversion unit 34 that generates an electric charge through photoelectric conversion of light transmitted through the filter unit 35 and accumulates an electric charge, which output signals, each generated based upon the electric charge generated in the photoelectric conversion unit 34, an exposure control unit (filter control unit 60) that switches between first exposure control, under which the filter unit 35 of the second pixel is set in a transmissive state and light having entered the first pixel and the second pixel undergoes photoelectric conversion, and second exposure control, under which the filter unit 35 of the second pixel is set in a light-shielding state and light having entered the first pixel undergoes photoelectric conversion while an electric charge accumulated in the photoelectric conversion unit 34 at the second pixel is held at the photoelectric conversion unit 34, and an output control unit (system control unit 110) that first executes the first exposure control so as to output signals from the first pixel and specific second pixels among the second pixels and then executes the second exposure control so as to output signals from the first pixel and second pixels other than the specific second pixels, among the second pixels. This structure makes it possible to read out pixel signals from all the still image pixels while preventing the frame rate for video shooting from becoming lowered.

(2) The electronic camera 1 comprises a first pixel, having a photoelectric conversion unit 34 that generates an electric charge through photoelectric conversion of incident light having entered therein and accumulates the electric charge, which outputs a signal generated based upon the electric charge generated at the photoelectric conversion unit 34, second pixels, each having a filter unit 35 that switches between a light-shielding state in which incident light is blocked and a transmissive state in which incident light is transmitted and a photoelectric conversion unit 34 that generates an electric charge through photoelectric conversion of light transmitted through the filter units 35 and accumulates the electric charge, which output signals, each generated based upon the electric charge generated in the photoelectric conversion unit 34, an exposure control unit (control unit 4) that switches between first exposure control, under which the filter unit 35 of the second pixel is set in a transmissive state and light having entered the first pixel and the second pixel undergoes photoelectric conversion, and second exposure control, under which the filter unit 35 of the second pixel is set in a light-shielding state and light having entered the first pixel undergoes photoelectric conversion while an electric charge accumulated in the photoelectric conversion unit 34 at the second pixel is held at the photoelectric conversion unit 34, and an output control unit (control unit 4) that first executes the first exposure control so as to output signals from the first pixel and specific second pixels among the second pixels and then executes the second exposure control so as to output signals from the first pixel and second pixels other than the specific second pixels among the second pixels. This structure makes it possible to read out pixel signals from all the still image pixels while preventing the frame rate for video shooting from becoming lowered.

(3) In the present embodiment, still image pixel signals generated based upon electric charges resulting from photoelectric conversion executed with uniform timing are read out over a plurality of different frames. This means that still image data can be generated by using the pixel signals generated based upon the electric charges obtained through photoelectric conversion executed with the same timing. As a result, the quality of a still image of, for instance, a moving subject can be improved.

(4) In the present embodiment, a pixel 10 is set in a light-shielding state by controlling its filter unit 35 so as to allow the photoelectric conversion unit 34 to hold an electric charge generated through photoelectric conversion. As a result, the area of the image sensor can be reduced compared to the area of an image sensor that includes storage elements each disposed in correspondence to one of the pixels. In addition, since separate storage elements are not provided, the area of the photoelectric conversion units 34 does not need to be reduced.

The following variations are also within the scope of the present invention and one of the variations or a plurality of variations may be adopted in combination with the embodiment described above.

(Variation 1)

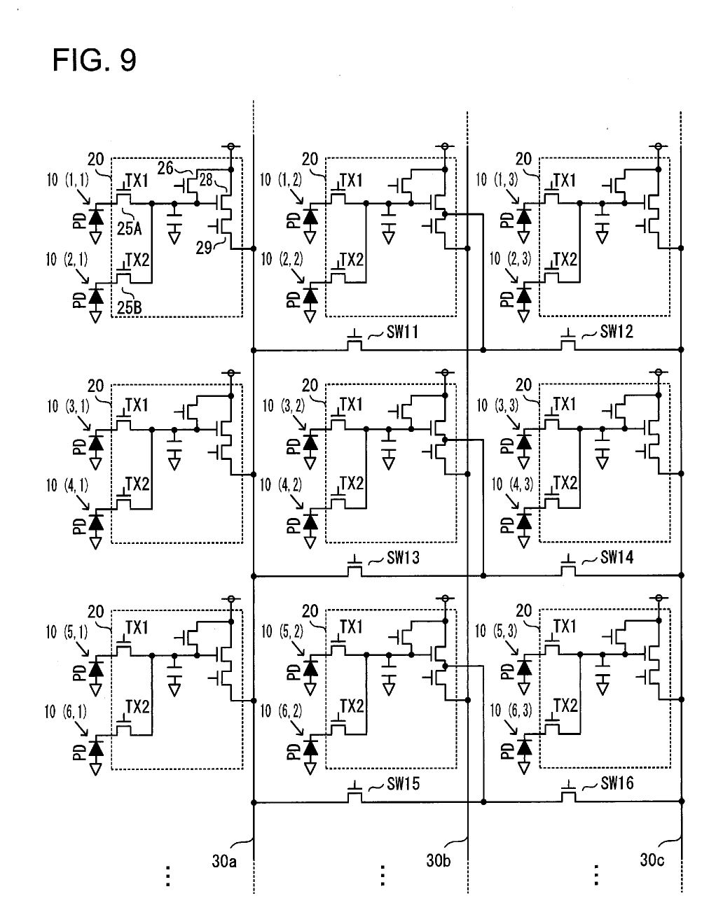

FIG. 9 is a circuit diagram showing the structure assumed in part of the image sensor according to variation 1. An image sensor 3 in variation 1 assumes a structure in which a readout unit 20 is shared by two pixels 10. A pixel 10 (1, 1) through a pixel 10 (6, 3) each include a PD. A pixel 10 (1, 2) and a pixel 10 (4, 2) are video pixels selected by the video image readout unit 111. An example of a method for reading out pixel signals will be described below.

For the (N)th frame, the image sensor 3 reads out pixel signals at pixels (1, 1), (1, 2) and (1, 3) respectively to the vertical signal lines 30a through 30c. Once these pixel signals are read out, the image sensor 3 reads out pixel signals at pixels (4, 1), (4, 2) and (4, 3) respectively to the vertical signal lines 30a through 30. In addition, during the readout for the (N)th frame, the image sensor 3 sets pixels that are not the readout targets for the (N)th frame into a light-shielding state so that electric charges generated through photoelectric conversion are accumulated (held) in the photoelectric conversion units 34 at the respective pixels.

For the (N+1)th frame, the image sensor 3 reads out pixel signals at pixels (2, 1), (1, 2) and (2, 3) respectively to the vertical signal lines 30a through 30c. In addition, once these pixel signals are read out, the image sensor 3 reads out pixel signals at pixels (5, 1), (4, 2) and (5, 3) respectively to the vertical signal lines 30a through 30. For the (N+2)th frame, the image sensor 3 reads out pixel signals at pixels (3, 1), (1, 2) and (3, 3) respectively to the vertical signal lines 30a through 30c. In addition, once these pixel signals are read out, the image sensor 3 reads out pixel signals at pixels (6, 1), (4, 2) and (6, 3) respectively to the vertical signal lines 30a through 30.

For the (N+3)th frame, the image sensor 3 reads out a pixel signal at the pixel (1, 2) to the vertical signal line 30b, reads out a pixel signal at a pixel (3, 2) to the vertical signal line 30a via a switch SW13, and reads out a pixel signal at a pixel (6, 2) to the vertical signal line 30c via a switch SW16. Once the pixel signals at the pixels (1, 2), (3, 2) and (6, 2) are read out, the image sensor 3 reads out a pixel signal at the pixel (4, 2) to the vertical signal line 30b, reads out a pixel signal at a pixel (2, 2) to the vertical signal line 30a via a switch SW11 and reads out a pixel signal at a pixel (5, 2) to the vertical signal line 30c via the switch SW16.

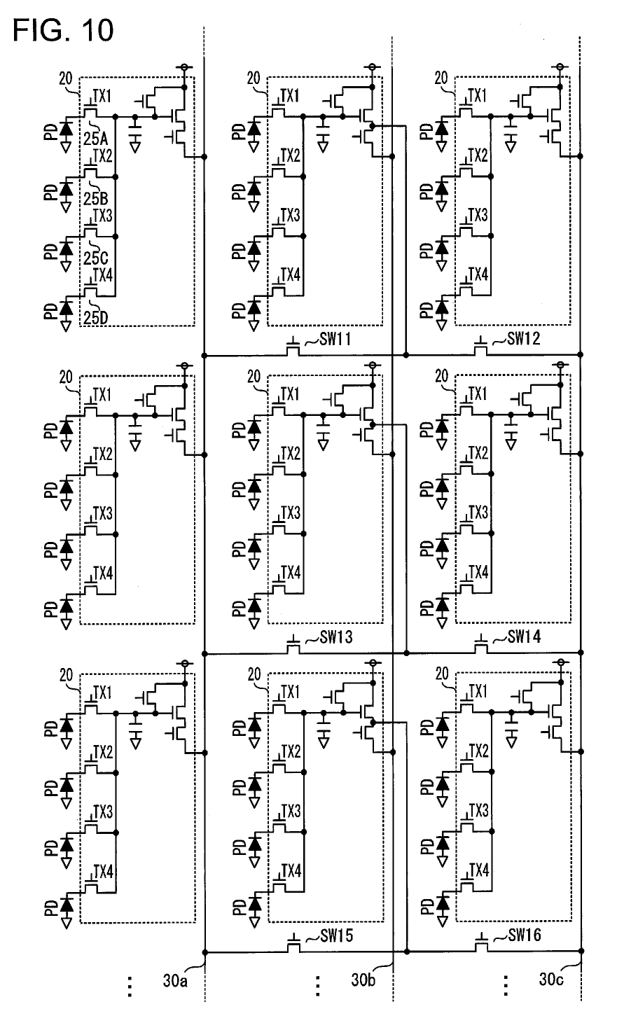

As described above, pixel signals are read out via the switches SW11 through SW16, which are connected between the vertical signal lines, in variation 1 so as to make it possible to read out pixel signals from all the still image pixels while preventing the frame rate for video shooting from becoming lowered. In addition, since a readout unit 20 is shared by two pixels 10, the image sensor in variation 1 allows its chip area to be reduced. It is to be noted that a single readout unit 20 may be shared by more than two pixels. For instance, a single readout unit 20 may be shared among four pixels 10, as shown in FIG. 10.

(Variation 2)

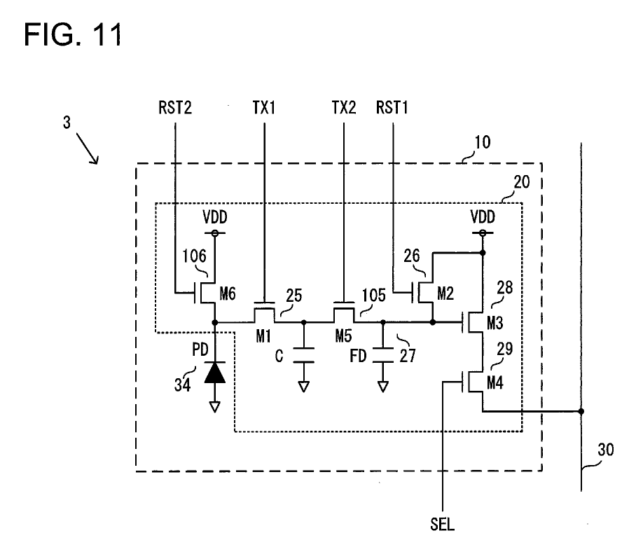

In the embodiment and the variation thereof described above, a pixel 10 is set in a light-shielding state so as to allow its photoelectric conversion unit 34 to function as a storage unit where a signal (electric charge) is stored. As an alternative, a capacitor C may be disposed in correspondence to each pixel 10 so as to use the capacitor C as a storage unit, as shown in FIG. 11. For instance, electric charges generated at the photoelectric conversion units 34 in the individual pixels 10 may be transferred to the respective capacitors C via first transfer units 25 so as to accumulate (hold) the electric charges at the capacitors C at the image sensor. In order to read out the pixel signal at a given pixel 10, the image sensor transfers the electric charge accumulated at the capacitor C to the floating diffusion 27 via a second transfer unit 105. The image sensor then sets the signal SEL to high level so as to output the pixel signal at the pixel 10 to the vertical signal line 30 via the amplifier unit 28 and the selection unit 29.

(Variation 3)

In the embodiment and the variations thereof described above, pixels 10 are configured with transistors, the drive control of which is executed based upon two values corresponding to low level and high level. However, pixels 10 may be configured with transistors, the drive control of which is executed based upon three values.

(Variation 4)

In the embodiment and the variations thereof described above, the filter units 35 each include three filters constituted with an EC layer that produces R (red) color, an EC layer that produces G (green) color and an EC layer that produces B (blue) color. As an alternative, the filter units 35 may each include three filters constituted with an EC layer that produces Mg (magenta) color, an EC layer that produces Ye (yellow) color and an EC layer that produces Cy (cyan) color. In addition, the filter units 35 may be variable filters constituted with liquid crystal. It is to be noted that instead of forming the filter units 35 as variable filters, the filter units 35 may be formed as light-shielding members such as MEMS shutters.

It is to be noted that the filter units 35 may be each constituted by combining a color filter that includes a filter through which light at a first wavelength is transmitted, a filter through which light at a second wavelength, greater than the first wavelength, is transmitted and a filter through which light at a third wavelength, greater than the second wavelength, is transmitted, with a filter that can be switched to a transmissive state in which light is transmitted or to a light-shielding state in which light is shielded. For instance, the filter units 35 may each be formed by combining a color filter through which light assuming wavelength ranges different from one another is transmitted (e.g. an RGB color filter or an MgYeCy color filter) and a variable filter (e.g. a liquid crystal filter or an MEMS shutter) that can be adjusted to a transmissive state or to a light-shielding state. In addition, the filter units 35 may be each constituted by combining a variable color filter that allows a transmission light wavelength range to be adjusted, as explained earlier, and a variable filter that can be adjusted to either a transmissive state or to a light-shielding state.

(Variation 5)

In the embodiment and the variations thereof described above, in a filter unit 35 in a “light-shielding state” described above, incident light does not need to be completely blocked. A structure in which a slight leak of light from each filter unit 35 occurs is also within the scope of the present invention. In such a case, the pixel signal can be corrected by using a black level correction technology of the known art.

(Variation 6)

In the embodiment and the variations thereof described above, the filter units 35 at the pixels 10 are controlled so that R pixels, G pixels and B pixels are set in a Bayer array pattern. As an alternative, the filter units 35 at the individual pixels 10 may be controlled so as to use them as W pixels with W (white) filter units 35 and as BK pixels with BK (black) filter units 35. In this case, the control unit 4 is able to generate monochrome image data based upon the pixel signals output from the image sensor 3.

(Variation 7)

In the embodiment and the variations thereof described above, the photoelectric conversion units are each constituted with a photodiode. As an alternative, photoelectric conversion units each constituted with a photoelectric conversion film (organic photoelectric film) may be used.

(Variation 8)

The image sensor 3 having been described in reference to the embodiment and the variations thereof may be adopted in a camera, a smart phone, a tablet, a built-in camera in a PC, an on-vehicle camera, a camera installed in an unmanned aircraft (such as a drone or a radio-controlled airplane) and the like.

As long as the features characterizing the present invention remain intact, the present invention is not limited to the particulars of the embodiment and the variations thereof described above. Any other mode conceivable within the scope of the technical teaching of the present invention is within the scope of the present invention.

The disclosure of the following priority application is herein incorporated by reference:

Japanese Patent Application No. 2016-192251 filed Sep. 29, 2016

### REFERENCE SIGNS LIST

3 image sensor, 10 pixel, 4a video image generation unit, 4b still image generation unit, 35 filter unit, 60 filter control unit, 110 system control unit

1-13. (canceled)

14. An image sensor, comprising:
a plurality of pixels, each having a filter unit that can be switched to a light-shielding state in which light is blocked or to a transmissive state in which light is transmitted, a photoelectric conversion unit that generates an electric charge through photoelectric conversion of light having been transmitted through the filter unit, and an output unit that outputs a signal generated based upon the electric charge generated in the photoelectric conversion unit; and
a control unit that first outputs signals through output units of specific pixels among the plurality of pixels and then sets filter units of the pixels other than the specific pixels in a light-shielding state so as to allow signals to be output through the output units thereof.

15. The image sensor according to claim 14, wherein:
the control unit sets the filter units of the pixels other than the specific pixels in a light-shielding state so as to allow signals generated based upon electric charges generated in the photoelectric conversion units while the filter units are set in a transmissive state, to be output from the output units of the pixels other than the specific pixels.

16. The image sensor according to claim 14, wherein:
the plurality of pixels each generate an electric charge in the photoelectric conversion unit while the filter unit is in a transmissive state; and
the control unit first allows signals to be output from the output units of the specific pixels and then sets the filter units of the pixels other than the specific pixels in a light-shielding state so as to allow signals, generated based upon electric charges generated in the photoelectric conversion units while the filter units are in a transmissive state, to be output from the output units of the pixels other than the specific pixels.

17. The image sensor according to claim 14, wherein:
the specific pixels each generate an electric charge in the photoelectric conversion unit thereof while signals are being output from the output units of the pixels other than the specific pixels.

18. A camera, comprising:
the image sensor according to claim 14; and
a generation unit that generates video image data based upon signals output from the output units of the specific pixels and generates still image data based upon signals output from the output units of the pixels other than the specific pixels.

19. An image sensor, comprising:
a first filter unit that can be switched to a light-shielding state in which light is blocked or to a transmissive state in which light is transmitted; a first photoelectric conversion unit that generates an electric charge through photoelectric conversion of light having been transmitted through the first filter unit; a first output unit that outputs a signal generated based upon the electric charge generated in the first photoelectric conversion unit;
a second filter unit that can be switched to a light-shielding state in which light is blocked or to a transmissive state in which light is transmitted; a second photoelectric conversion unit that generates an electric charge through photoelectric conversion of light having been transmitted through the second filter unit; a second output unit that outputs a signal generated based upon the electric charge generated in the second photoelectric conversion unit; and
a control unit that allows a signal to be output from the second output unit by setting the second filter unit in a light-shielding state after having a signal output from the first output.

20. The image sensor according to claim 19, wherein:
the control unit sets the second filter unit in a light-shielding state so as to allow a signal, generated based upon an electric charge generated in the second photoelectric conversion unit while the second filter unit is in a transmissive state, to be output from the second output unit.

21. The image sensor according to claim 19, wherein:
the second photoelectric conversion unit generates an electric charge through photoelectric conversion of incident light having entered therein while the second filter unit thereof is in a transmissive state; and
the control unit first allows a signal to be output from the first output and then sets the second filter unit in a light-shielding state so as to output a signal generated based upon an electric charge generated in the second photoelectric conversion unit while the second filter unit is in a transmissive state, from the second output unit.

22. The image sensor according to claim 19, wherein:
the first photoelectric conversion unit generates an electric charge through photoelectric conversion of light having entered therein while a signal is being output from the second output unit.

23. A camera, comprising:
the image sensor according to claim 19; and
a generation unit that generates video image data based upon a signal output from the output unit of the first pixel and generates still image data based upon a signal output from the output unit of the second pixel.

24. The image sensor according to claim 14, wherein:
the control unit sets filter units of the pixels other than the specific pixels in a light-shielding state so as to allow signals to be output from the output units of the specific pixels and the output units of the pixels other than the specific pixels.

25. The image sensor according to claim 14, wherein:
the control unit executes first exposure control under which the filter units of the plurality of pixels are set in a transmissive state and light having entered the photoelectric conversion units of the plurality of pixels undergoes photoelectric conversion, and second exposure control under which the filter units of the specific pixels are set in a transmissive state and light having entered the photoelectric conversion units of the specific pixels undergoes photoelectric conversion.

26. The image sensor according to claim 25, wherein:
the control unit sets the filter units of the pixels other than the specific pixels in a light-shielding state while performing the second exposure control so as to allow electric charge generated through the first exposure control to be held.

27. The image sensor according to claim 25, wherein:
the control unit allows a signal, generated based upon an electric charge generated in the photoelectric conversion units of the pixels other than the specific pixels through performing the first exposure control, to be output from the output units of the pixels other than the specific pixels while performing the second exposure control.

28. The image sensor according to claim 25, wherein:
the control unit first executes the first exposure control to allow a signal to be output from the output units of the specific pixels and then executes the second exposure control to allow the signal to be output from the output units of the pixels other than the specific pixels.

29. The image sensor according to claim 19, wherein:
the control unit allows a signal to be output from the first output unit and the second output unit by setting the second filter unit in a light-shielding state.

30. The image sensor according to claim 19, wherein:
the control unit executes first exposure control under which the first filter unit and the second filter unit are set in a transmissive state and light having entered the first photoelectric conversion unit and the second photoelectric conversion unit undergoes photoelectric conversion, and second exposure control under which the first filter unit is set in a transmissive state and the second filter unit is set in a light-shielding state and light having entered the first photoelectric conversion unit undergoes photoelectric conversion.

31. The image sensor according to claim 22, wherein:
the control unit sets the second filter unit in a light-shielding state while performing the second exposure control so as to allow electric charge generated by the second exposure control unit through performing the first exposure control to be held.

32. The image sensor according to claim 30, wherein:
the control unit allows a signal, generated based upon an electric charge generated in the second photoelectric conversion unit through performing the first exposure control, to be output from the second output unit while performing the second exposure control.

33. The image sensor according to claim 30, wherein:
the control unit executes first exposure control to allow a signal to be output from the first output unit and then executes the second exposure control to allow the signal to be output from the second output unit.
